(19) United States
(12) Patent Application Publication
(10) Pub. No.: US 2026/0190273 A1
(43) Pub. Date: Jul. 2, 2026

(54) Server Information Handling System Power Distribution System Attachment Mechanism

(71) Applicant: Dell Products L.P., Round Rock, TX (US)

(72) Inventors: Tung-Yu Chien, Taipei (TW); Chin-An Huang, Taipei (TW)

(21) Appl. No.: 19/004,548

(22) Filed: Dec. 30, 2024

(51) Int. Cl. H05K 7/14; G06F 1/18

(52) U.S. Cl. CPC H05K 7/1492; G06F 1/189; H05K 7/1452

(57) ABSTRACT

A power system for an information handling system. The system includes a power supply unit; a power distribution system coupled to the power supply unit, and a power distribution system connection mechanism, the power distribution system connection mechanism including a plurality of connector pins, the plurality of connector pins being included with the power distribution system; and a plurality of connector sockets coupled to a circuit board, each of the plurality of connector sockets being configured with a floating movement capability, each of the plurality of connector pins being positioned to mate with a respective connector socket when the power distribution system is attached to the circuit board.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server type information handling system with power distribution system attachment mechanism.

In one embodiment, the invention relates to a power distribution system connection mechanism for use with a power distribution system of an information handling system, comprising: a plurality of connector pins, the plurality of connector pins being included with a power distribution system; and a plurality of connector sockets coupled to a circuit board, each of the plurality of connector sockets being configured with a floating movement capability, each of the plurality of connector pins being positioned to mate with a respective connector socket when the power distribution system is attached to the circuit board.

In another embodiment, the invention relates to a power system for an information handling system comprising a power supply unit; a power distribution system coupled to the plurality of power supply units and a power distribution system connection mechanism, the power distribution system connection mechanism comprising: a plurality of connector pins, the plurality of connector pins being included with a power distribution system; and a plurality of connector sockets coupled to a circuit board, each of the plurality of connector sockets being configured with a floating movement capability, each of the plurality of connector pins being positioned to mate with a respective connector socket when the power distribution system is attached to the circuit board.

In another embodiment, the invention relates to a system comprising: a chassis; a plurality of components contained within the chassis; and, a power system providing power to the plurality of components, the power system including the power system including a power supply unit and a power distribution system coupled to the power supply unit, and a power distribution system connection mechanism, the power distribution system connection mechanism comprising: a plurality of connector pins, the plurality of connector pins being included with a power distribution system; and a plurality of connector sockets coupled to a circuit board, each of the plurality of connector sockets being configured with a floating movement capability, each of the plurality of connector pins being positioned to mate with a respective connector socket when the power distribution system is attached to the circuit board.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A, 4B, 4C, 4D and 4E, generally referred to as FIG. 4, show views of a power system for an information handling system.

FIGS. 5A, 5B, 5C and 5D, generally referred to as FIG. 5, shows views of a power distribution system of a power system for an information handling system.

FIGS. 6A, 6B, 6C and 6D, generally referred to as FIG. 6, show views of a power system.

FIGS. 7A, 7B and 7C, generally referred to as FIG. 7, show views of a power distribution system connector sockets.

### DETAILED DESCRIPTION

Various aspects of the present disclosure include an appreciation that server type information handling system designs are becoming increasingly challenging as a function of growing component size, increasing power requirements and increasing heat loads within the system. Various aspects of the present disclosure include an appreciation that it is known to provide information handling systems with a plurality of components. Various aspects of the present disclosure include an appreciation that graphics processing unit (GPU) modules (often referred to as accelerator add in cards (AICs) and drive modules are examples of components that are often included within an information handling system. Various aspects of the present disclosure include an appreciation that it may be desirable to provide an information handling system with an array of components. Various aspects of the present disclosure include an appreciation that it may be desirable to install an array of GPU modules within an information handling system.

Various aspects of the present disclosure include an appreciation that GPU modules are often configured to conform to form factor standards. Various aspects of the present disclosure include an appreciation that the card electromechanical (CEM) form factor standard is one such form factor standard. Various aspects of the disclosure include an appreciation that it is known to provide information handling systems with baseboard systems such as peripheral component interconnect express (PCIe) type baseboard systems.

Various aspects of the present disclosure include an appreciation that powering components within server type information handling system often require high capacity power distribution designs. Various aspects of the present disclosure include an appreciation that high capacity power distribution can be an especially challenging aspect of server type information handling system design. Various aspects of the present disclosure include an appreciation that these issues are especially present in systems which are designed with a plurality of components such as a plurality of GPUs or a plurality of drives. These issues are also especially present in systems which are designed with an array of AICs, such as in systems which are designed to support artificial intelligence (AI) workloads.

Various aspects of the present disclosure include an appreciation that server type information handling system designs can often include a plurality of high capacity power supplies to provide redundant power to a plurality of components within the server type information handling system such as GPU modules as well as other high powered components. With one such design six, 3200 Watt power supplies are included within the information handling system to provide high and redundant power to a plurality of components. Distributing the power from these power supplies can present design challenges. For example, components of the power distribution are often physically located between the power supplies and the plurality of components resulting in the power distribution system being part of the depth of the critical stack within the information handling system chassis. Various aspects of the present disclosure include an appreciation that the depth of the power distribution system has implications for rack support (due for example, to product depth), cost (due for example to the size of components of the power distribution system), or a combination thereof.

Various aspects of the present disclosure include an appreciation that certain power distribution solutions include power distribution structures which include multiple connectors. Various aspects of the present disclosure include an appreciation that certain multiple connector configurations can require connectors which include coplanar and perpendicular connection aspects. Various aspects of the present disclosure include an appreciation that certain multiple connector configurations with multiple connectors can require enhanced dimension tolerance.

Various aspects of the present disclosure include an appreciation that it would be desirable to provide a power distribution solution with a power distribution system attachment mechanism which can address these issues.

A system and method are disclosed for providing a server type information handling system with power system which includes a power distribution system and a power distribution system attachment mechanism. In certain embodiments, the power distribution system includes an auxiliary power board, power distribution bars mounted on the auxiliary power board, vertical power distribution bar components, or a combination thereof. In certain embodiments, the power distribution system attachment mechanism includes high power connector pins and high power connector sockets. In certain embodiments, the power distribution system includes the high power connector pins. In certain embodiments, a system circuit board of the power system includes the high power connector sockets. In certain embodiments, a power supply unit system of the power system includes high power connector sockets.

In certain embodiments, the power distribution system attachment mechanism is configured to provide attachment dimension tolerance between the connector pins and the connector sockets. In certain embodiments, the connector sockets are configured with a floating movement capability. In certain embodiments, the floating movement capability is maintained at the connection between the high power connector sockets and the system circuit board. In certain embodiments, the floating movement capability is maintained at the connection between the high power connector sockets and the a power supply unit circuit board. In certain embodiments, the floating movement capability facilitates the attachment dimension tolerance between the connector pins and the connector sockets.

In certain embodiments, the power distribution system includes power distribution bars mounted on the auxiliary power board. In certain embodiments, the power distribution bars extend horizontally across the auxiliary power board. In certain embodiments, the power distribution system includes vertical power distribution bar components. In certain embodiments, the positive and ground vertical power distribution bar components are interlaced such that the positive vertical power distribution bar component is electrically coupled to the positive power distribution bar and the ground vertical power distribution bar component is electrically coupled to the ground power distribution bar.

In certain embodiments, the high power connector pins include positive high power connector pins and ground high power connector pins. In certain embodiments, the high power connector sockets of the system board include positive high power connector sockets and ground high power connector sockets. In certain embodiments, the high power connector sockets of the power supply system include positive high power connector sockets and ground high power connector sockets, or a combination thereof. In certain embodiments, the positive high power connector pins mate with the positive high power connector sockets of one or more of the system board and the power supply system. In certain embodiments, the ground high power connector pins mate with the ground high power connector sockets of one or more of the system circuit board and the power supply system. In certain embodiments, lengths of one or more high power connector pins can be customized to absorb connection tolerances of the power distribution system connection mechanisms.

Such a power distribution system advantageously provides a reduced footprint power distribution solution for high power accelerator server type information handling systems. Such a power distribution system attachment mechanism system advantageously provides a power distribution solution which provides a stable power delivery system from a power supply unit system to components of the information handling system. Such a power distribution system attachment mechanism system advantageously provides a power distribution solution which is easy to service.

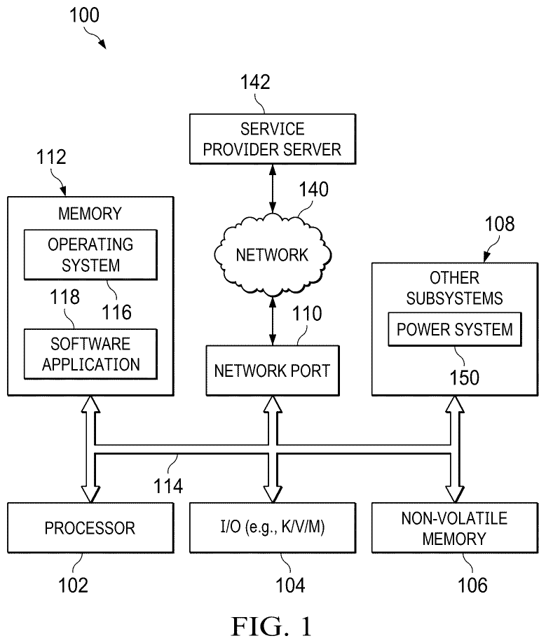

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a power system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the power system 150 is part of a power environment which includes a power system and a plurality of components coupled to the power system. In certain embodiments, the plurality of components are arranged as an array of components. In certain embodiments, the plurality of components includes a plurality of GPUs, a plurality of drives, or a combination thereof. In certain embodiments, the plurality of GPUs, the plurality of drives, or a combination thereof, are designed to support artificial intelligence (AI) workloads.

In certain embodiments, the power system 150 includes one or more power supplies as well as a power distribution system. In certain embodiments, the power distribution system includes an auxiliary power board, power distribution bars mounted on opposing sides of the auxiliary power board, interlaced vertical power distribution bar components, or a combination thereof.

In certain embodiments, the power distribution system includes positive and ground power distribution bars mounted on opposing sides of the auxiliary power board. In certain embodiments, the positive power distribution bar extends horizontally across one side of the auxiliary power board. In certain embodiments, the ground power distribution bar extends horizontally across another side of the auxiliary power board. In certain embodiments, the positive power distribution bar extends horizontally across a top side of the auxiliary power board. In certain embodiments, the ground power distribution bar extends horizontally across a bottom side of the auxiliary power board.

In certain embodiments, the power distribution system includes interlaced positive and ground vertical power distribution bar components. In certain embodiments, the positive and ground vertical power distribution bar components are interlaced such that the positive vertical power distribution bar component is electrically coupled to the positive power distribution bar and the ground vertical power distribution bar component is electrically coupled to the ground power distribution bar.

In certain embodiments, the positive vertical power distribution bar component includes a positive vertical power distribution bar component top portion, a positive vertical power distribution bar component bottom portion, a positive vertical power distribution bar component middle portion, or a combination thereof. In certain embodiments, the positive vertical power distribution bar component middle portion is physically coupled between the positive vertical power distribution bar component top portion and the positive vertical power distribution bar component bottom portion. In certain embodiments, the positive vertical power distribution bar component middle portion is electrically coupled to the positive vertical power distribution bar component top portion and the positive vertical power distribution bar component bottom portion. In certain embodiments, the positive vertical power distribution bar component top portion, the positive vertical power distribution bar component bottom portion and the positive vertical power distribution bar component middle portion are constructed from a single piece of material. In certain embodiments, the positive vertical power distribution bar component top portion, the positive vertical power distribution bar component bottom portion and the positive vertical power distribution bar component middle portion are constructed form a single piece of electrically conductive material.

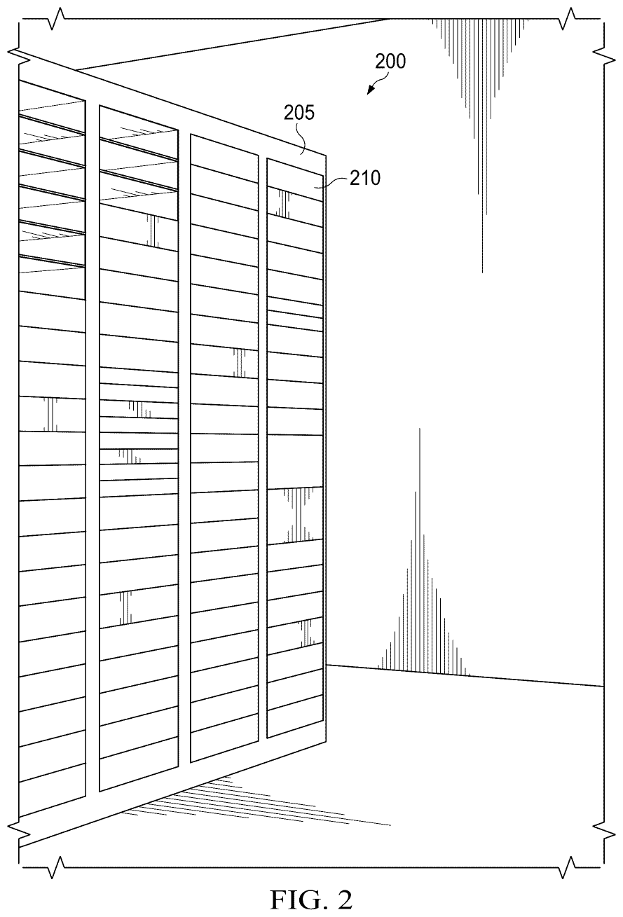

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

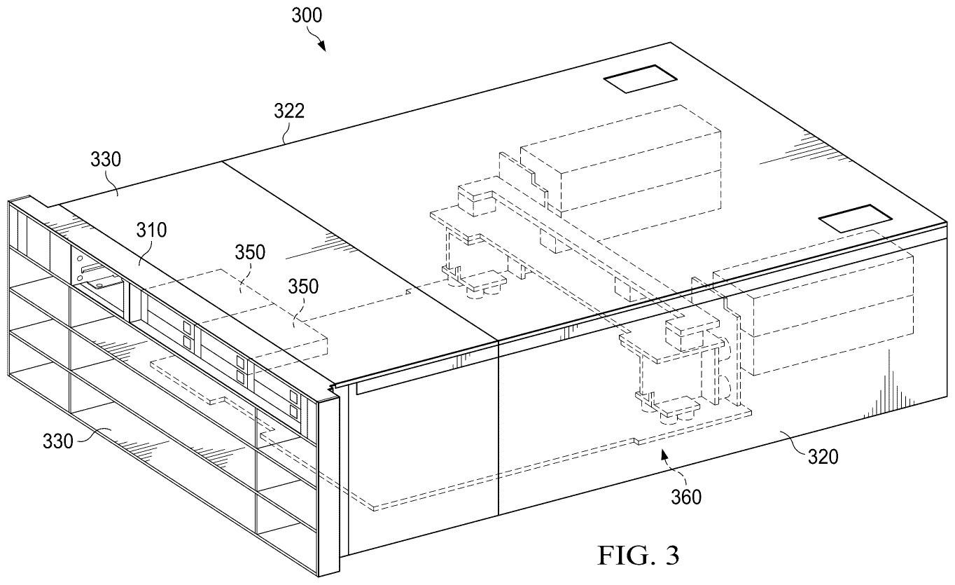

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the server system 300 includes one or more device bays 350. 360. In certain embodiments, the server system 300 includes a power environment 360. In certain embodiments, the power environment 360 corresponds to power system 150.

In certain embodiments, the power environment 360 is part of a power environment which includes a power system and a plurality of components coupled to the power system. In certain embodiments, the plurality of components are arranged as an array of components. In certain embodiments, the plurality of components includes a plurality of GPUs, a plurality of drives, or a combination thereof. In certain embodiments, the plurality of GPUs, the plurality of drives, or a combination thereof, are designed to support artificial intelligence (AI) workloads.

In certain embodiments, the power environment 360 includes one or more power supplies as well as a power distribution system. In certain embodiments, the power distribution system includes an auxiliary power board, power distribution bars mounted on opposing sides of the auxiliary power board, interlaced vertical power distribution bar components, or a combination thereof.

In certain embodiments, the power distribution system includes positive and ground power distribution bars mounted on opposing sides of the auxiliary power board. In certain embodiments, the positive power distribution bar extends horizontally across one side of the auxiliary power board. In certain embodiments, the ground power distribution bar extends horizontally across another side of the auxiliary power board. In certain embodiments, the positive power distribution bar extends horizontally across a top side of the auxiliary power board. In certain embodiments, the ground power distribution bar extends horizontally across a bottom side of the auxiliary power board.

In certain embodiments, the power distribution system includes interlaced positive and ground vertical power distribution bar components. In certain embodiments, the positive and ground vertical power distribution bar components are interlaced such that the positive vertical power distribution bar component is electrically coupled to the positive power distribution bar and the ground vertical power distribution bar component is electrically coupled to the ground power distribution bar.

In certain embodiments, the positive vertical power distribution bar component includes a positive vertical power distribution bar component top portion, a positive vertical power distribution bar component bottom portion, a positive vertical power distribution bar component middle portion, or a combination thereof. In certain embodiments, the positive vertical power distribution bar component middle portion is physically coupled between the positive vertical power distribution bar component top portion and the positive vertical power distribution bar component bottom portion. In certain embodiments, the positive vertical power distribution bar component middle portion is electrically coupled to the positive vertical power distribution bar component top portion and the positive vertical power distribution bar component bottom portion. In certain embodiments, the positive vertical power distribution bar component top portion, the positive vertical power distribution bar component bottom portion and the positive vertical power distribution bar component middle portion are constructed from a single piece of material. In certain embodiments, the positive vertical power distribution bar component top portion, the positive vertical power distribution bar component bottom portion and the positive vertical power distribution bar component middle portion are constructed form a single piece of electrically conductive material.

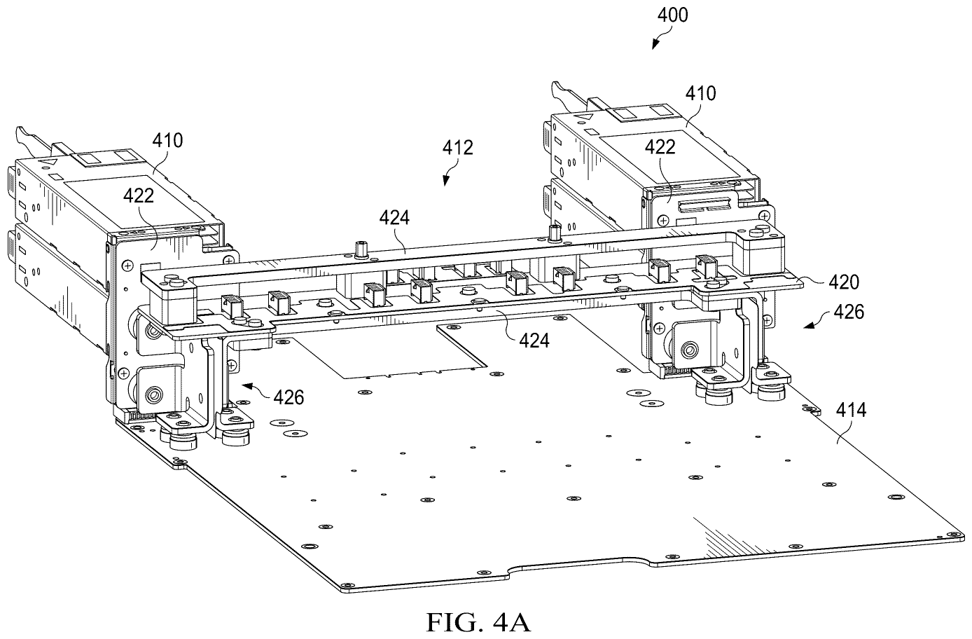

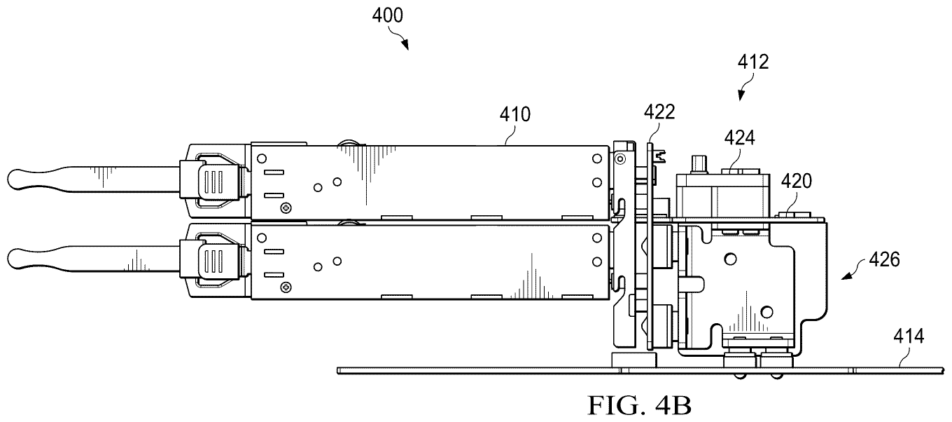

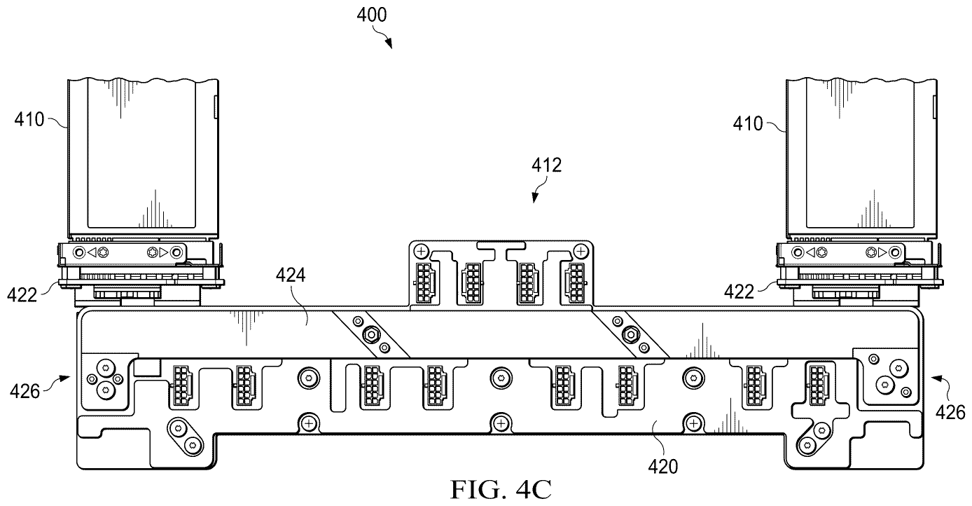

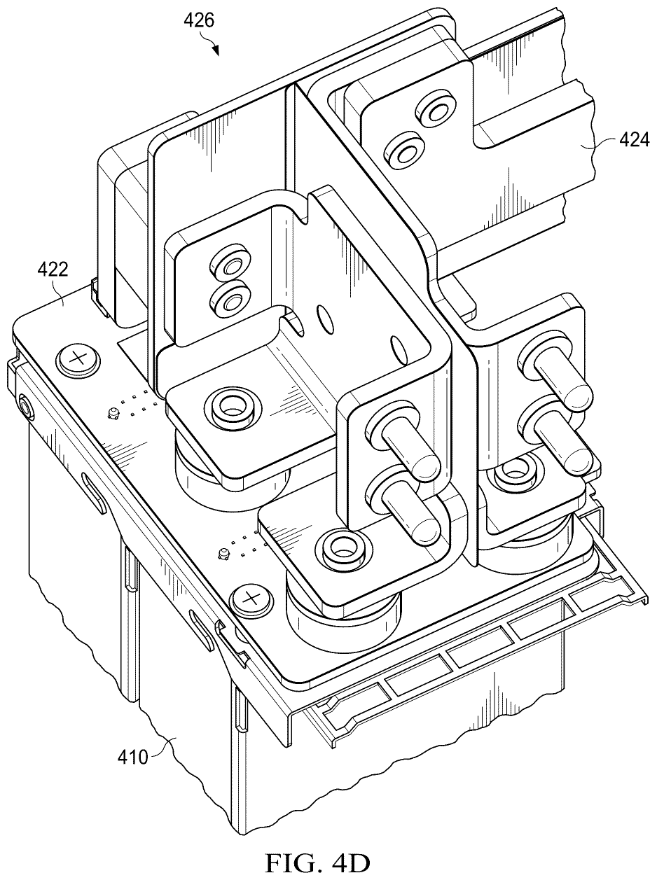

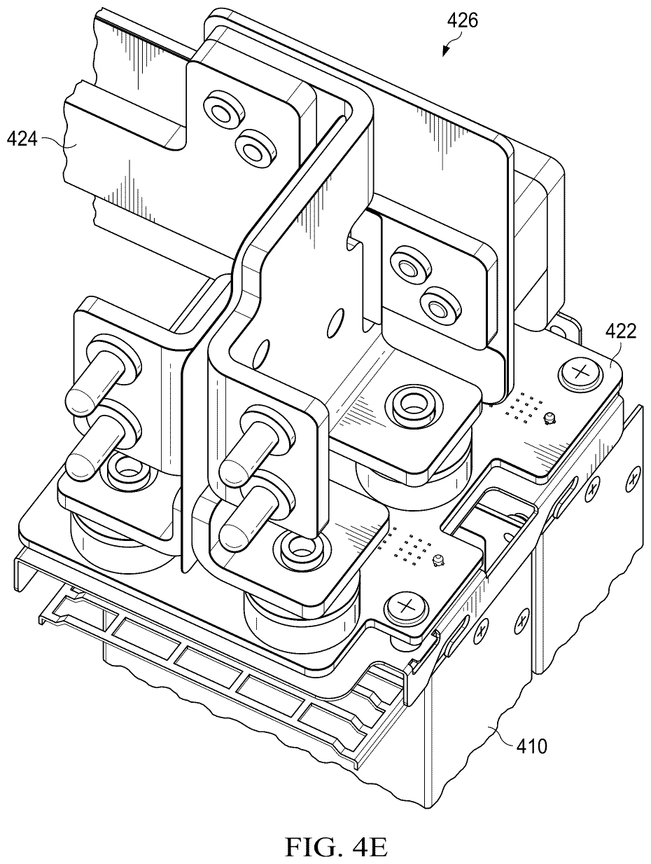

FIGS. 4A, 4B, 4C, 4D and 4E, generally referred to as FIG. 4, show views of a power system 400 for an information handling system. More specifically, FIG. 4A shows a perspective view of a power system 400. FIG. 4B shows a side view of a portion of a power system 400. FIG. 4C shows a top view of a portion of a power system 400. FIG. 4D shows a bottom perspective view of a first side portion of a power system 400. FIG. 4E shows a bottom perspective view of a second side portion of a power system 400. In certain embodiments, the power system 400 corresponds to power system 150.

In certain embodiments, the power system 400 includes one or more power supplies 410 a power distribution system 412, a system circuit board 414, or a combination thereof. In certain embodiments, the system circuit board 414 includes one or more of a motherboard, a planar circuit board, a high performance module circuit board, and a baseboard circuit board. In certain embodiments, the power distribution system 412 includes an auxiliary power board 420, one or more power supply boards 422, power distribution bars 424, vertical power distribution bar device 426, or a combination thereof. In certain embodiments, the power distribution bars 424 are mounted on opposing sides of the auxiliary power board 420. In certain embodiments, vertical power distribution bar components are configured as interlaced vertical power distribution bar components. As used herein, interlaced vertical power distribution components broadly refers to vertical power distribution components which are interspersed by alternation (i.e., positioned at alternating intervals) such that sets of vertical power distribution components occupy substantially (i.e. +/−20%) the same volume of space within the chassis of the information handling system.

In certain embodiments, the power distribution bars 424 include a positive power distribution bar, a ground power distribution bar, or a combination thereof. In certain embodiments, the positive power distribution bar and the ground power distribution bar are mounted on opposing sides of the auxiliary power board 420. In certain embodiments, the positive power distribution bar 420 extends horizontally across one side of the auxiliary power board. In certain embodiments, the ground power distribution bar extends horizontally across another side of the auxiliary power board 420. In certain embodiments, the positive power distribution bar extends horizontally across a top side of the auxiliary power board 420. In certain embodiments, the ground power distribution bar extends horizontally across a bottom side of the auxiliary power board 420.

In certain embodiments, each interlaced vertical power distribution bar component includes a positive vertical power distribution bar component, a ground vertical power distribution bar component, or a combination thereof. In certain embodiments, the positive vertical power distribution bar component and the ground vertical power distribution bar component are configured as interlaced positive and ground vertical power distribution bar components. In certain embodiments, the positive and ground vertical power distribution bar components are interlaced such that the positive vertical power distribution bar component is electrically coupled to the positive power distribution bar and the ground vertical power distribution bar component is electrically coupled to the ground power distribution bar. In certain embodiments, each interlaced vertical power distribution bar component 426 is physically coupled, electrically coupled, or a combination thereof, to one or more power supplies 410, the system circuit board 414, the auxiliary power board 420, a power supply board 422, the power distribution bars 424, or a combination thereof.

In certain embodiments, each positive vertical power distribution bar component 426 includes a positive vertical power distribution bar component top portion, a positive vertical power distribution bar component bottom portion, a positive vertical power distribution bar component middle portion, or a combination thereof. In certain embodiments, the positive vertical power distribution bar component middle portion is physically coupled between the positive vertical power distribution bar component top portion and the positive vertical power distribution bar component bottom portion. In certain embodiments, the positive vertical power distribution bar component middle portion is electrically coupled to the positive vertical power distribution bar component top portion and the positive vertical power distribution bar component bottom portion. In certain embodiments, the positive vertical power distribution bar component top portion, the positive vertical power distribution bar component bottom portion and the positive vertical power distribution bar component middle portion are constructed from a single piece of material. In certain embodiments, the positive vertical power distribution bar component top portion, the positive vertical power distribution bar component bottom portion and the positive vertical power distribution bar component middle portion are constructed form a single piece of electrically conductive material.

In certain embodiments, each ground vertical power distribution bar component 426 includes a ground vertical power distribution bar component top portion, a ground vertical power distribution bar component bottom portion, a ground vertical power distribution bar component middle portion, or a combination thereof. In certain embodiments, the ground vertical power distribution bar component middle portion is physically coupled between the ground vertical power distribution bar component top portion and the ground vertical power distribution bar component bottom portion. In certain embodiments, the ground vertical power distribution bar component middle portion is electrically coupled to the ground vertical power distribution bar component top portion and the ground vertical power distribution bar component bottom portion. In certain embodiments, the ground vertical power distribution bar component top portion, the ground vertical power distribution bar component bottom portion and the ground vertical power distribution bar component middle portion are constructed from a single piece of material. In certain embodiments, the ground vertical power distribution bar component top portion, the ground vertical power distribution bar component bottom portion and the ground vertical power distribution bar component middle portion are constructed form a single piece of electrically conductive material.

In certain embodiments, the interlaced vertical power distribution bar components 426 include first side interlaced vertical power distribution bar components, second side interlaced vertical power distribution bar components, or a combination thereof. In certain embodiments, the first side interlaced vertical power distribution bar components are positioned close to a first side edge of the power system 400. In certain embodiments, the second side interlaced vertical power distribution bar components are positioned close to a second side edge of the power system 400. In certain embodiments, the power distribution bars 424 extend between the first side edge of the power system and the second side edge of the power system.

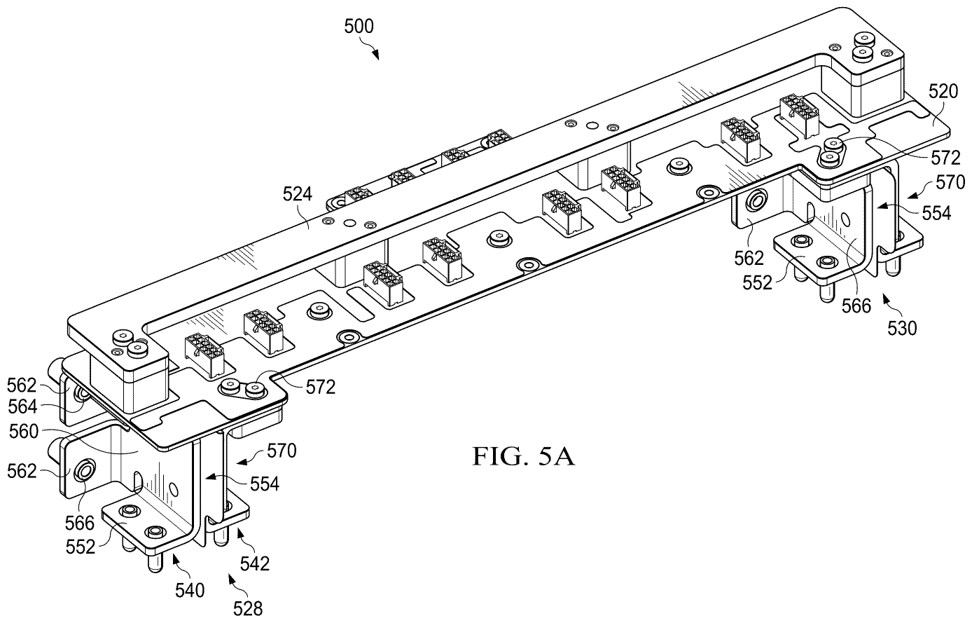

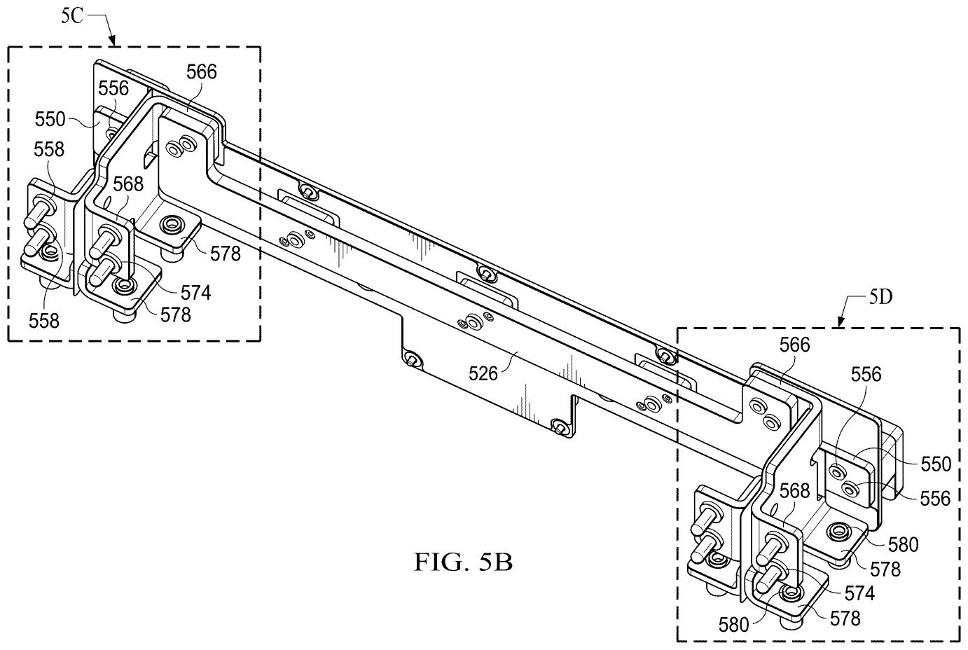

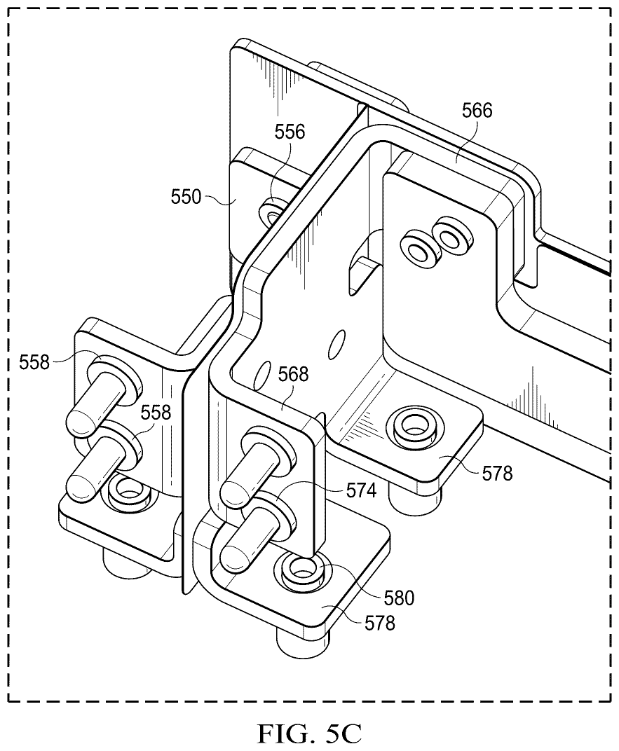

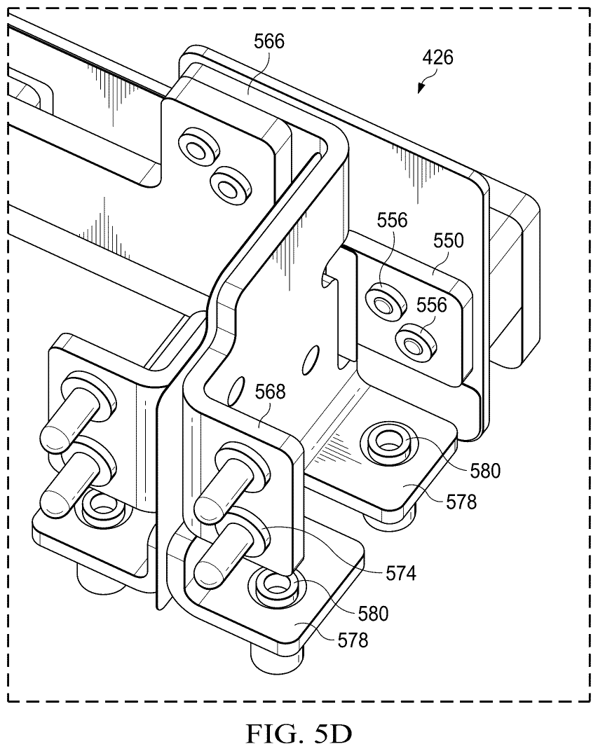

FIGS. 5A, 5B, 5C and 5D, generally referred to as FIG. 5, shows views of a power distribution system 500 of a power system for an information handling system. More specifically, FIG. 5A shows a front perspective view of a power distribution system 500. FIG. 5B shows a rear perspective view of a power distribution system 500. FIG. 5C shows a bottom perspective view of first side portion of a power distribution system 500. FIG. 5D shows a bottom perspective view of a second side portion of a power distribution system 500. In certain embodiments, the power distribution system 500 corresponds to power distribution system 412.

In certain embodiments, the power distribution system 500 includes an auxiliary power board 520, power distribution bars 524, 526, vertical power distribution bar components 528, 530, or a combination thereof. In certain embodiments, the power distribution bars 524, 526 are mounted on opposing sides of the auxiliary power board 520. In certain embodiments, the vertical power distribution bar components 528, 530 are configured as interlaced vertical power distribution bar components. As used herein, interlaced vertical power distribution components broadly refers to vertical power distribution components which are interspersed by alternation (i.e., positioned at alternating intervals) such that sets of vertical power distribution components occupy substantially (i.e. +/−20%) the same volume of space within the chassis of the information handling system. In certain embodiments, the volume of space is a substantially (i.e., +/−20%) rectangular prism volume of space.

In certain embodiments, the power distribution bars include a positive power distribution bar 524, a ground power distribution bar 526, or a combination thereof. In certain embodiments, the positive power distribution bar 524 and the ground power distribution bar 526 are mounted on opposing sides of the auxiliary power board 520. In certain embodiments, the positive power distribution bar 524 extends horizontally across one side of the auxiliary power board. In certain embodiments, the ground power distribution bar 526 extends horizontally across another side of the auxiliary power board 520. In certain embodiments, the positive power distribution bar 524 extends horizontally across a top side of the auxiliary power board 520. In certain embodiments, the ground power distribution bar 526 extends horizontally across a bottom side of the auxiliary power board 520.

In certain embodiments, the interlaced vertical power distribution bar component 528 includes a positive vertical power distribution bar component 540, a ground vertical power distribution bar component 542, or a combination thereof. In certain embodiments, the positive vertical power distribution bar component 540 and the ground vertical power distribution bar component 542 are configured as interlaced positive and ground vertical power distribution bar components. In certain embodiments, the positive vertical power distribution component 540 and ground vertical power distribution bar component 542 are interlaced such that the positive vertical power distribution bar component 540 is electrically coupled to the positive power distribution bar 524 and the ground vertical power distribution bar component 542 is electrically coupled to the ground power distribution bar 526. In certain embodiments, each interlaced vertical power distribution bar component is physically coupled, electrically coupled, or a combination thereof, to one or more power supplies 510, the system circuit board 514, the auxiliary power board 520, a power supply board 522, the power distribution bars 524, or a combination thereof.

In certain embodiments, the positive vertical power distribution bar component 540 includes a positive vertical power distribution bar component top portion 550, a positive vertical power distribution bar component bottom portion 552, a positive vertical power distribution bar component middle portion 554, or a combination thereof. In certain embodiments, the positive vertical power distribution bar component middle portion 554 is physically coupled between the positive vertical power distribution bar component top portion 550 and the positive vertical power distribution bar component bottom portion 552. In certain embodiments, the positive vertical power distribution bar component middle portion 554 is electrically coupled to the positive vertical power distribution bar component top portion 550 and the positive vertical power distribution bar component bottom portion 552. In certain embodiments, the positive vertical power distribution bar component top portion 550, the positive vertical power distribution bar component bottom portion 552 and the positive vertical power distribution bar component middle portion 554 are constructed from a single piece of material. In certain embodiments, the positive vertical power distribution bar component top portion 550, the positive vertical power distribution bar component bottom portion 552 and the positive vertical power distribution bar component middle portion 554 are constructed form a single piece of electrically conductive material.

In certain embodiments, the positive vertical power distribution bar component top portion 550 is configured as a substantially (i.e. +/−20%) rectangular tab. In certain embodiments, positive vertical power distribution bar component top portion 550 extends substantially (i.e. +/−20%) perpendicular from a top edge of the positive vertical power distribution bar middle portion 554. In certain embodiments, positive vertical power distribution bar component top portion 550 extends substantially (i.e. +/−20%) horizontally from a top edge of the positive vertical power distribution bar middle portion 554. In certain embodiments, the positive vertical power distribution bar component top portion 550 includes one or more fastener portions 556.

In certain embodiments, the positive vertical power distribution bar component bottom portion 552 is configured as a substantially (i.e. +/−20%) rectangular tab. In certain embodiments, positive vertical power distribution bar component bottom portion 552 extends substantially (i.e. +/−20%) perpendicular from a bottom edge of the positive vertical power distribution bar middle portion 554. In certain embodiments, positive vertical power distribution bar component bottom portion 552 extends substantially (i.e. +/−20%) horizontally from a bottom edge of the positive vertical power distribution bar middle portion 554. In certain embodiments, the positive vertical power distribution bar component bottom portion 552 includes one or more fastener portions 558.

In certain embodiments, the positive vertical power distribution bar component middle portion 554 includes a main housing portion 560. In certain embodiments, the main housing portion 560 is substantially (i.e. +/−20%) rectangular. In certain embodiments, the positive vertical power distribution bar component middle portion 554 includes one or more power supply mounting tabs 562. In certain embodiments, each power supply mounting tab 562 is configured as a substantially (i.e. +/−20%) rectangular tab. In certain embodiments, each power supply mounting tab 562 extends substantially (i.e. +/−20%) perpendicular from a side edge of the main housing portion 560. In certain embodiments, each power supply mounting tab 562 extends substantially (i.e. +/−20%) vertically along the side edge of the main housing portion 560. In certain embodiments, each power supply mounting tab 562 defines a power supply fastener aperture 564.

In certain embodiments, the ground vertical power distribution bar component 542 includes a ground vertical power distribution bar component top portion 566, a ground vertical power distribution bar component bottom portion 568, a ground vertical power distribution bar component middle portion 570, or a combination thereof. In certain embodiments, the ground vertical power distribution bar component middle portion 570 is physically coupled between the ground vertical power distribution bar component top portion 566 and the ground vertical power distribution bar component bottom portion 568. In certain embodiments, the ground vertical power distribution bar component middle portion 570 is electrically coupled to the ground vertical power distribution bar component top portion 566 and the ground vertical power distribution bar component bottom portion 568. In certain embodiments, the ground vertical power distribution bar component top portion 566, the ground vertical power distribution bar component bottom portion 568 and the ground vertical power distribution bar component middle portion 570 are constructed from a single piece of material. In certain embodiments, the ground vertical power distribution bar component top portion 566, the ground vertical power distribution bar component bottom portion 568 and the ground vertical power distribution bar component middle portion 570 are constructed form a single piece of electrically conductive material.

In certain embodiments, the ground vertical power distribution bar component top portion 566 is configured as a substantially (i.e. +/−20%) rectangular tab. In certain embodiments, ground vertical power distribution bar component top portion 566 extends substantially (i.e. +/−20%) perpendicular from a top edge of the ground vertical power distribution bar middle portion 570. In certain embodiments, ground vertical power distribution bar component top portion 566 extends substantially (i.e. +/−20%) horizontally from a top edge of the ground vertical power distribution bar middle portion 570. In certain embodiments, the ground vertical power distribution bar component top portion 566 includes one or more fastener portions 572.

In certain embodiments, the ground vertical power distribution bar component bottom portion 568 is configured as a substantially (i.e. +/−20%) rectangular tab. In certain embodiments, ground vertical power distribution bar component bottom portion 568 extends substantially (i.e. +/−20%) perpendicular from a bottom edge of the ground vertical power distribution bar middle portion 570. In certain embodiments, ground vertical power distribution bar component bottom portion 568 extends substantially (i.e. +/−20%) horizontally from a bottom edge of the ground vertical power distribution bar middle portion 570. In certain embodiments, the ground vertical power distribution bar component bottom portion 568 includes one or more fastener portions 574.

In certain embodiments, the ground vertical power distribution bar component middle portion 570 includes a main housing portion 576. In certain embodiments, the main housing portion 576 is substantially (i.e. +/−20%) rectangular. In certain embodiments, the ground vertical power distribution bar component middle portion 570 includes one or more power supply mounting tabs 578. In certain embodiments, each power supply mounting tab 578 is configured as a substantially (i.e. +/−20%) rectangular tab. In certain embodiments, each power supply mounting tab 578 extends substantially (i.e. +/−20%) perpendicular from a side edge of the main housing portion 576. In certain embodiments, each power supply mounting tab 578 extends substantially (i.e. +/−20%) vertically along the side edge of the main housing portion 576. In certain embodiments, each power supply mounting tab 578 defines a power supply fastener aperture 580.

In certain embodiments, the interlaced vertical power distribution bar components include first side interlaced vertical power distribution bar components 528, a second side interlaced vertical power distribution bar component 530, or a combination thereof. In certain embodiments, the first side interlaced vertical power distribution bar component 528 is positioned close to a first side edge of the power system 500. In certain embodiments, the second side interlaced vertical power distribution bar component 530 is positioned close to a second side edge of the power system 500. In certain embodiments, the power distribution bars 524 extend between the first side edge of the power system and the second side edge of the power system.

In certain embodiments, the positive vertical power distribution bar component top portion 550 and the ground vertical power distribution bar component top portion 566 of the second side interlaced vertical power distribution bar component 530 are interlaced. In certain embodiments, the positive vertical power distribution bar component top portion 550 extends substantially (i.e. +/−20%) perpendicular from a top edge of the positive vertical power distribution bar middle portion 554 such that the positive vertical power distribution bar component top portion 550 is vertically positioned over the ground vertical power distribution bar component 542 of the second side interlaced vertical power distribution bar component 530. In certain embodiments, the ground vertical power distribution bar component top portion 566 extends substantially (i.e. +/−20%) perpendicular from a top edge of the ground vertical power distribution bar middle portion 570 such that the ground vertical power distribution bar component top portion 550 is vertically positioned over the positive vertical power distribution bar component 540 of the second side interlaced vertical power distribution bar component 530.

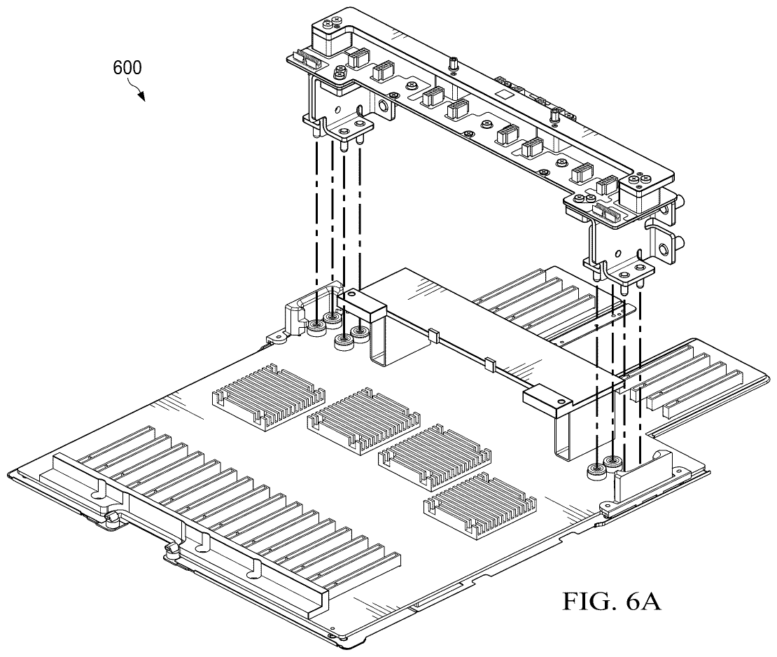

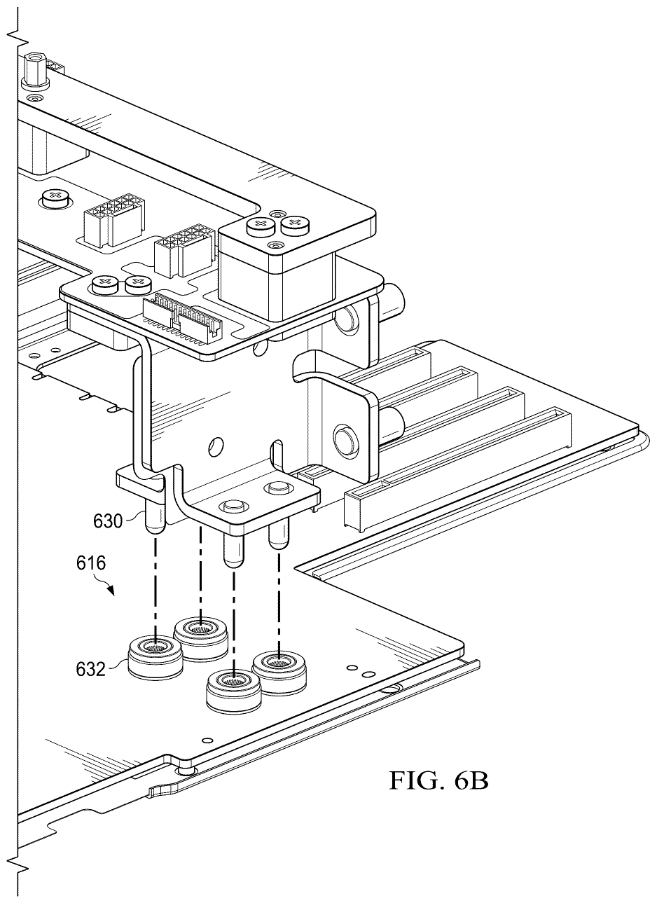

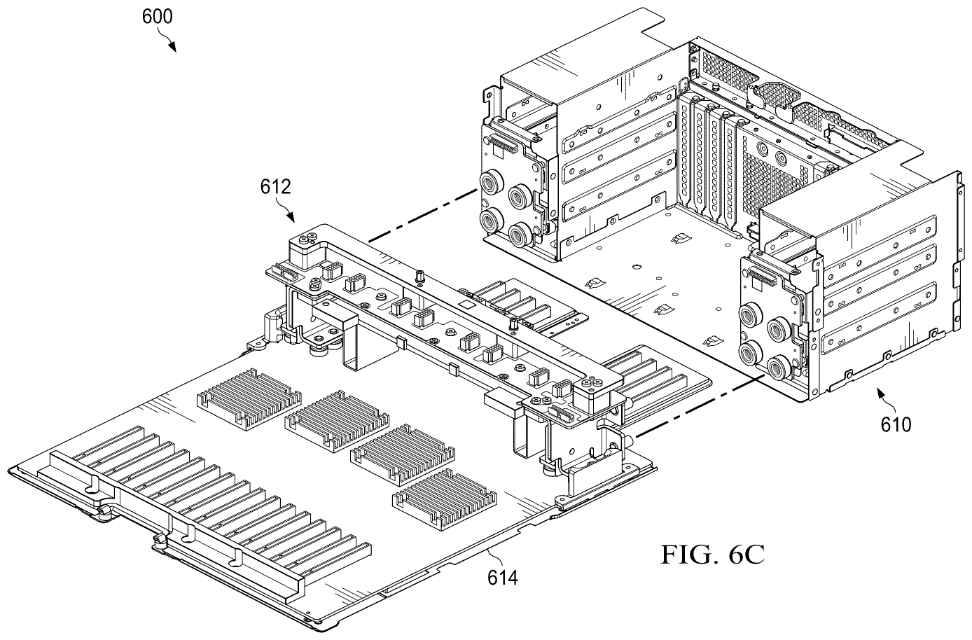

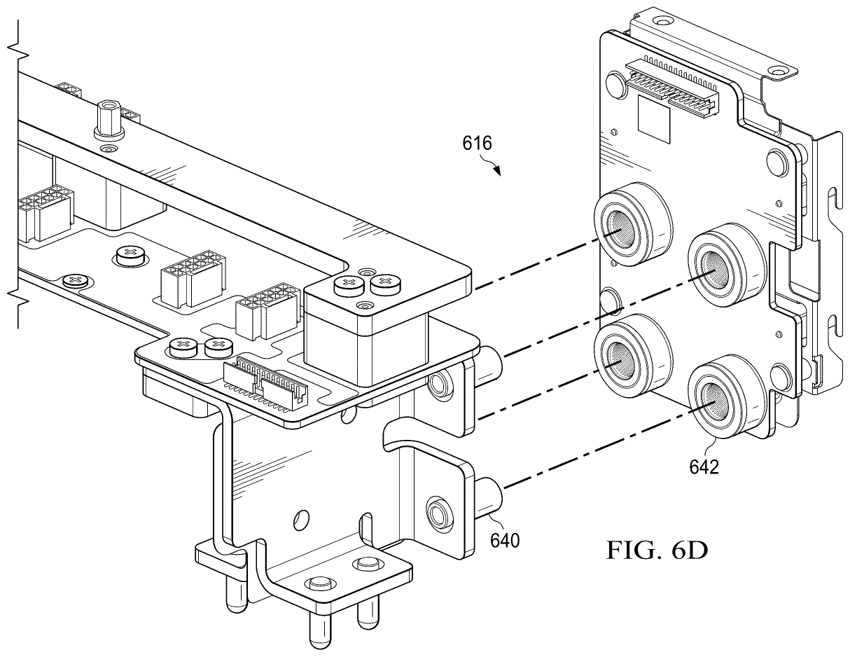

FIGS. 6A, 6B, 6C and 6D, generally referred to as FIG. 6, show views of a power system. More specifically, FIG. 6A shows an exploded perspective view of a power system 600. FIG. 6B shows an exploded perspective view of a portion of a power system 600. FIG. 6C shows an exploded perspective view of a power system 600. FIG. 6D shows an exploded perspective view of a portion of a power system 600. In certain embodiments, the power system 600 corresponds to power system 150.

In certain embodiments, the power system 600 includes a power supply system 610, a power distribution system 612, a system circuit board 614, power distribution system connection mechanisms 616, or a combination thereof. In certain embodiments, the power distribution system 612 includes an auxiliary power board, power distribution bars mounted on the auxiliary power board, vertical power distribution bar components, or a combination thereof. In certain embodiments, the system circuit board 614 includes one or more of a motherboard, a planar circuit board, a high performance module circuit board, and a baseboard circuit board. In certain embodiments, the power distribution system extraction mechanism includes a horizontal extraction portion, vertical extraction portions, one or more extraction manipulation components, or a combination thereof.

In certain embodiments, the power distribution system 612 includes power distribution bars mounted on the auxiliary power board. In certain embodiments, the power distribution bars extend horizontally across the auxiliary power board. In certain embodiments, the power distribution system includes vertical power distribution bar components. In certain embodiments, the positive and ground vertical power distribution bar components are interlaced such that the positive vertical power distribution bar component is electrically coupled to the positive power distribution bar and the ground vertical power distribution bar component is electrically coupled to the ground power distribution bar.

In certain embodiments, the power distribution system connection mechanisms 616 includes system circuit board high power connector pins 630 and system circuit board high power connector sockets 632. In certain embodiments, the power distribution system 612 includes the high power connector pins 630. In certain embodiments, the system circuit board 614 includes the high power connector sockets 632. In certain embodiments, the power distribution system connection mechanisms 616 includes power supply system high power connector pins 640 and power supply system high power connector sockets 642. In certain embodiments, the power distribution system 612 includes the power supply system high power connector pins 640. In certain embodiments, power supply unit system 610 also includes the power supply system high power connector sockets 644.

In certain embodiments, the high power connector pins 630, 640 include positive high power connector pins, ground high power connector pins, or a combination thereof. In certain embodiments, the high power connector sockets 632, 642 include positive high power connector sockets, ground high power connector sockets, or a combination thereof. In certain embodiments, the positive high power connector pins mate with respective positive high power connector sockets. In certain embodiments, the ground high power connector pins mate with respective ground high power connector sockets. In certain embodiments, lengths of one or more high power connector pins 630, 640 can be customized to absorb connection tolerances of the power distribution system connection mechanisms 616. In certain embodiments, dimensions (e.g., diameters) of connector pins and connector socket openings may be sized according to the power that will be conducted through the connector pin and connector socket.

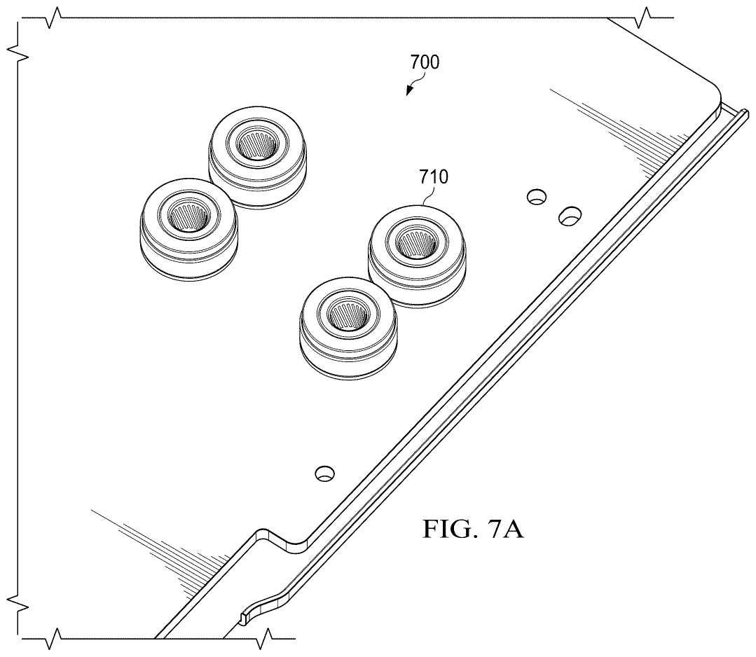

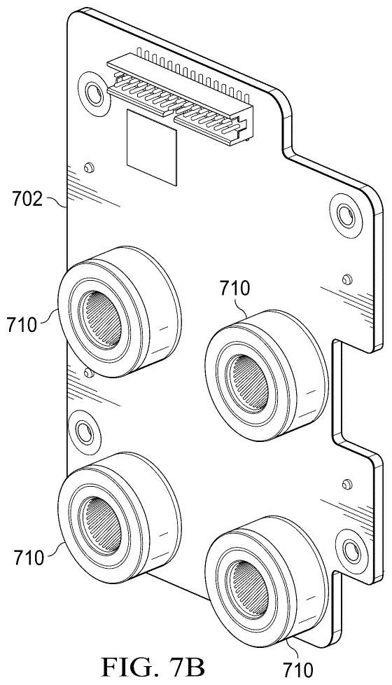

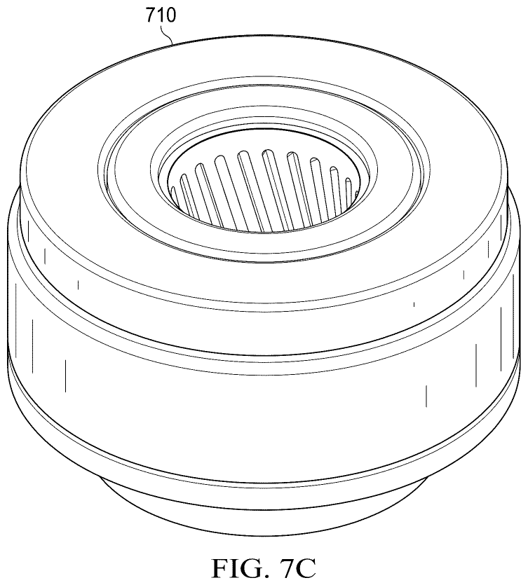

FIGS. 7A, 7B and 7C, generally referred to as FIG. 7, show views of power distribution system connector sockets. More specifically, FIG. 7A shows a perspective view of a connector socket system 700. FIG. 7B shows a perspective view of a connector socket system 702. FIG. 7C shows a perspective view of a connector socket system connector socket 710.

In certain embodiments, a power distribution system connection mechanism includes one or more connector socket systems 700, 702. In certain embodiments, each connector socket system 700, 702 includes one or more connector socket system connector socket 710. In certain embodiments, a system circuit board includes one or more connector socket system 700. In certain embodiments, a power supply unit system also includes one or more connector socket system 702.

In certain embodiments, high power connector pins include positive high power connector pins, ground high power connector pins, or a combination thereof. In certain embodiments, the high power connector sockets 700, 702 include positive high power connector sockets, ground high power connector sockets, or a combination thereof. In certain embodiments, positive high power connector pins mate with the positive high power connector sockets. In certain embodiments, ground high power connector pins mate with the ground high power connector sockets. In certain embodiments, lengths of one or more high power connector pins can be customized to absorb connection tolerances of the power distribution system connection mechanisms. In certain embodiments, dimensions (e.g., diameters) of one or more high power connector pins can be adjusted based upon power to be carried by the high power connectors.

In certain embodiments, each connector socket system connector socket 710 includes a power socket body 720. In certain embodiments, the power socket body 720 defines a socket opening and a socket recess. In certain embodiments, a conductor component 730 is mounted within the socket recess. In certain embodiments, the conductor component 730 includes a circular portion as well as a plurality of conductor elements. In certain embodiments, the plurality of conductor elements extend into the socket recess. In certain embodiments, the plurality of conductor elements are electrically coupled with the circular portion. In certain embodiments, the circuit portion, the plurality of conductor elements, or a combination thereof, are configured to electrically interact with a respective connector pin of the power distribution system attachment mechanism. In certain embodiments, the socket opening of a connector socket system connector socket is configured to mate with a diameter of a corresponding high power connector pin.

In certain embodiments, the power distribution system attachment mechanism is configured to provide attachment dimension tolerance between the connector pins and the connector sockets. In certain embodiments, each connector socket is configured with a floating movement capability. As used herein, a floating movement capability broadly refers to an attachment configuration for a connector socket in which the connector socket is adjustable via a range of movement within an opening in which the connector socket is installed while being affixed to a board which defines the opening. In certain embodiments, the floating movement capability is maintained at the connection between a high power connector socket and a system circuit board. In certain embodiments, the floating movement capability is maintained at a connection between a high power connector socket and a power supply unit circuit board. In certain embodiments, the floating movement capability facilitates the attachment dimension tolerance between the connector pins and the connector sockets.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A power distribution system connection mechanism for use with a power distribution system of an information handling system, comprising:
a plurality of connector pins, the plurality of connector pins being included with a power distribution system; and
a plurality of connector sockets coupled to a circuit board, each of the plurality of connector sockets being configured with a floating movement capability, each of the plurality of connector pins being positioned to mate with a respective connector socket when the power distribution system is attached to the circuit board.

2. The power distribution system connection mechanism of claim 1, wherein:
the power distribution system includes a vertical power distribution component; and,
the plurality of connector pins are included within the vertical power distribution component.

3. The power distribution system connection mechanism of claim 2, wherein:
the vertical power distribution component includes a vertical power distribution bar component top portion, a vertical power distribution bar component bottom portion, a vertical power distribution bar component middle portion, the vertical power distribution bar component middle portion being electrically coupled to the vertical power distribution bar component top portion and the vertical power distribution bar component bottom portion; and,
the plurality of connector pins are coupled to at least one of the vertical power distribution bar component middle portion and the vertical power distribution bar component bottom portion.

4. The power distribution system connection mechanism of claim 3, wherein:
the vertical power distribution bar component middle portion includes a power supply mounting tab; and,
a connector pin is attached to the power supply mounting tab.

5. The power distribution system connection mechanism of claim 3, wherein:
the vertical power distribution bar component bottom portion is configured as a tab; and,
a connector pin is attached to the tab of the vertical power distribution bar component bottom portion.

6. The power distribution system connection mechanism of claim 1, wherein:
the circuit board includes at least one of a system circuit board and a power supply unit system circuit board.

7. A power system for an information handling system comprising:
a power supply unit;
a power distribution system coupled to the power supply unit; and,
a power distribution system connection mechanism, the power distribution system connection mechanism comprising
a plurality of connector pins, the plurality of connector pins being included with the power distribution system; and
a plurality of connector sockets coupled to a circuit board, each of the plurality of connector sockets being configured with a floating movement capability, each of the plurality of connector pins being positioned to mate with a respective connector socket when the power distribution system is attached to the circuit board.

8. The power system of claim 7, wherein:
the power distribution system includes a vertical power distribution component; and,
the plurality of connector pins are included within the vertical power distribution component.

9. The power system of claim 8, wherein:
the vertical power distribution component includes a vertical power distribution bar component top portion, a vertical power distribution bar component bottom portion, a vertical power distribution bar component middle portion, the vertical power distribution bar component middle portion being electrically coupled to the vertical power distribution bar component top portion and the vertical power distribution bar component bottom portion; and,
the plurality of connector pins are coupled to at least one of the vertical power distribution bar component middle portion and the vertical power distribution bar component bottom portion.

10. The power system of claim 9, wherein the power distribution system further comprises:
the vertical power distribution bar component middle portion includes a power supply mounting tab; and,
a connector pin is attached to the power supply mounting tab.

11. The power system of claim, wherein:
the vertical power distribution bar component bottom portion is configured as a tab; and,
a connector pin is attached to the tab of the vertical power distribution bar component bottom portion.

12. The power system of claim 7, wherein:
the circuit board includes at least one of a system circuit board and a power supply unit system circuit board.

13. A system comprising:
a chassis;
a plurality of components contained within the chassis; and,
a power system providing power to the plurality of components, the power system including a power supply unit and a power distribution system coupled to the power supply unit, and a power distribution system connection mechanism, the power distribution system connection mechanism comprising;
a plurality of connector pins, the plurality of connector pins being included with the power distribution system; and
a plurality of connector sockets coupled to a circuit board, each of the plurality of connector sockets being configured with a floating movement capability, each of the plurality of connector pins being positioned to mate with a respective connector socket when the power distribution system is attached to the circuit board.

14. The system of claim 13, wherein:
the power distribution system includes a vertical power distribution component; and,
the plurality of connector pins are included within the vertical power distribution component.

15. The system of claim 14, wherein:
the vertical power distribution component includes a vertical power distribution bar component top portion, a vertical power distribution bar component bottom portion, a vertical power distribution bar component middle portion, the vertical power distribution bar component middle portion being electrically coupled to the vertical power distribution bar component top portion and the vertical power distribution bar component bottom portion; and,
the plurality of connector pins are coupled to at least one of the vertical power distribution bar component middle portion and the vertical power distribution bar component bottom portion.

16. The system of claim 14, wherein the power distribution system further comprises:
the vertical power distribution bar component middle portion includes a power supply mounting tab; and,
a connector pin is attached to the power supply mounting tab.

17. The system of claim 14, wherein:
the vertical power distribution bar component bottom portion is configured as a tab; and,
a connector pin is attached to the tab of the vertical power distribution bar component bottom portion.

18. The system of claim 13, wherein:
the circuit board includes at least one of a system circuit board and a power supply unit system circuit board.
